(19) United States
(12) Patent Application Publication
(10) Pub. No.: US 2004/0000877 A1
(43) Pub. Date: Jan. 1, 2004

(54) Application specific integrated circuit and method of operation

(76) Inventors: Bruce McKay Morton, Snohomish, WA (US); Thomas James Rollins, Boynton Beach, FL (US)

Correspondence Address: Randi L. Dulaney, Motorola, Inc., Law Department, 8000 West Sunrise Boulevard, Fort Lauderdale, FL, 33322, US

(21) Appl. No.: 10/186,577

(22) Filed: Jul. 1, 2002

(51) Int. Cl. G09G 3/10; H05B 37/00; H01L 41/04; H04M 1/00

(52) U.S. Cl. 315/169.3; 315/160; 315/209 PZ; 310/311; 455/572

(57) ABSTRACT

An ASIC (138) that is useful in electronic devices that include a piezoelectric transducer (112), and an electroluminescent lamp (130), includes a DC to DC converter (402), a piezoelectric drive signal input (424), a piezoelectric transducer drive amplifier (404), an oscillator (406), and an electroluminescent drive amplifier (408). The DC to DC converter (402) boosts a voltage of an external power source (132) and powers the piezoelectric drive amplifier (404), and the electroluminescent drive amplifier (408). An externally supplied piezoelectric drive signal is input through the piezoelectric drive signal input (424) to a piezoelectric transducer drive amplifier input (426), and amplified. An amplified version of the signal is output on a pair of differential outputs (432). The electroluminescent drive amplifier (408) is driven by a signal generated by the oscillator (406).

### BACKGROUND OF THE INVENTION

1. Field of the Invention

The present invention relates to integrated circuits and particularly to application specific integrated circuits.

2. Description of Related Art

As portable electronic devices (e.g., pages, two-way pagers, personal digital assistants, and wireless telephones) are developed, there continues to be an interest in adding functionality while maintaining or reducing size, and lowering manufacturing costs.

Electroluminescent lamps that provide high quality back lighting for portable electronic device displays have been introduced. Piezoelectric transducers that are capable of generating tactile and audio alerts have been developed. In addition to providing simple audio alerts (e.g., beeps), such transducers are capable of emitting audio, and generating tactile feedback. In order to operate the aforementioned piezoelectric transducers and electroluminescent lamps relatively high driving voltages are required. The voltages required usually exceed the voltage that characterizes included power sources (e.g., batteries) by a factor of ten or more.

### BRIEF DESCRIPTION OF THE FIGURES

The present invention will be described by way of exemplary embodiments, but not limitations, illustrated in the accompanying drawings in which like references denote similar elements, and in which:

FIG. 1 is schematic partial cut-away top view of a portable electronic apparatus according to the preferred embodiment of the invention.

FIG. 2 is a schematic sectional side view of the portable electronic apparatus shown in FIG. 1.

FIG. 3 is a block diagram of the portable electronic apparatus shown in FIG. 1.

FIG. 4 shows a block diagram of an application specific integrated circuit that is used in the portable electronic apparatus shown in FIG. 1 according to the preferred embodiment of the invention, along with an external boost circuit.

FIG. 5 is a flow chart of a method of operating the application specific integrated circuit shown in FIG. 4 according to the preferred embodiment of the invention.

FIG. 6 is a perspective view of a piezoelectric transducer that is used in the portable electronic apparatus shown in FIGS. 1-2

FIG. 7 is a magnified view of a portion of the piezoelectric transducer shown in FIG. 6.

### DETAILED DESCRIPTION OF THE PREFERRED EMBODIMENTS

As required, detailed embodiments of the present invention are disclosed herein; however, it is to be understood that the disclosed embodiments are merely exemplary of the invention, which can be embodied in various forms. Therefore, specific structural and functional details disclosed herein are not to be interpreted as limiting, but merely as a basis for the claims and as a representative basis for teaching one skilled in the art to variously employ the present invention in virtually any appropriately detailed structure. Further, the terms and phrases used herein are not intended to be limiting; but rather, to provide an understandable description of the invention.

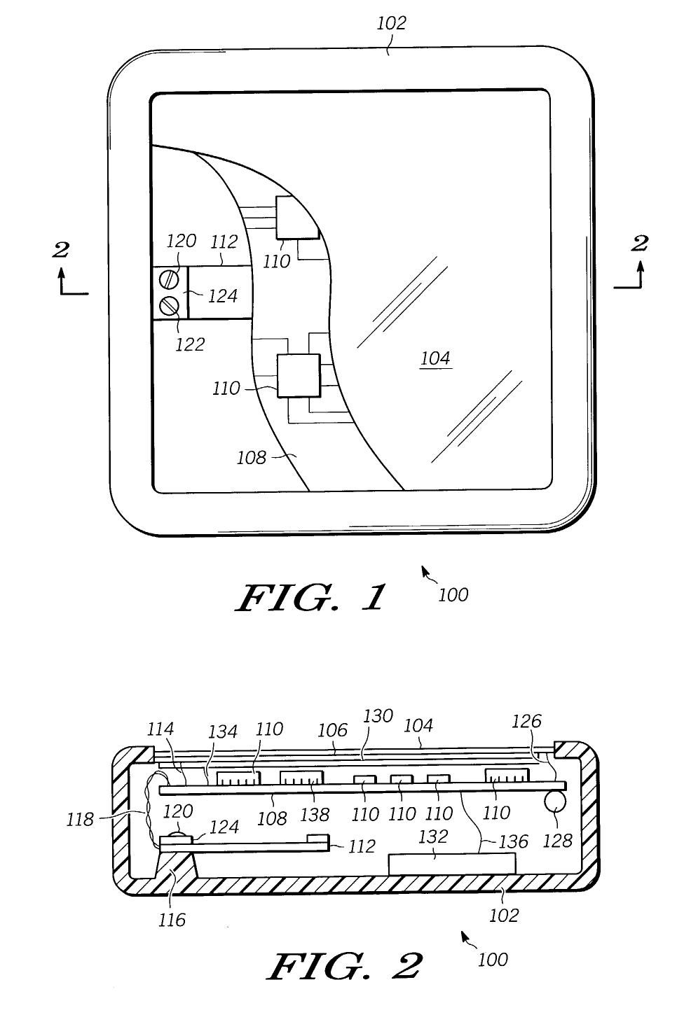

FIG. 1 is a schematic partial cut-away top view of a portable electronic apparatus 100 according to the preferred embodiment of the invention and FIG. 2 is a schematic sectional side view of the portable electronic apparatus 100 shown in FIG. 1. The portable electronic apparatus 100 preferably comprises a touch screen equipped wireless communication device. However, the invention is not so limited and can be applied to devices of various types including but not limited to cell phones, pagers, hand held electronic games, and talking electronic dictionaries. The portable electronic apparatus 100, as shown in FIG. 1, includes a housing 102 that supports a touch screen 104, disposed over a flat panel display 106 (e.g., a liquid crystal display) that in turn overlies an electroluminescent lamp 130. The electroluminescent lamp 130 serves to backlight the flat panel display 106. A power source 132 is located within the housing 102. The power source 132 preferably comprises a battery.

A printed circuit board 108 is enclosed within the housing 102. The circuit board 108 supports and electrically couples a plurality of electric circuit components 110, including an electroluminescent lamp and piezoelectric transducer drive Application Specific Integrated Circuit 138, hereinafter to be referred to as ASIC 138. A first electrical coupling 126 connects circuits on the printed circuit board 108 to the touch screen 104. A second electrical coupling 114 connects circuits on the printed circuit board 108 to the display 1O6. A third electrical coupling 134 connects circuits on the printed circuit board 108 to the electroluminescent lamp 130. An antenna 128 is located within the housing 102, and electrically coupled to circuits on the printed circuit board 108.

A piezoelectric transducer 112 is mounted on a mounting boss 116 within the housing 102. A first screw 120, a second screw 122, and a clamping plate 124 are used to clamp the electromechanical transducer 212 to the mounting boss 116. A fourth electrical coupling 118 connects the piezoelectric transducer 112 to circuits on the printed circuit board 108. A fifth electrical coupling 136 couples the power source 132 to electrical circuits on the printed circuit board 108.

The piezoelectric transducer 112 is used for outputting audio, generating vibratory alerts, vibrating in response to a complex driving signal. U.S. patent application Ser. No. 10/160,590 filed Jun. 3, 2002 (attorney docket no. PT03357U, Inventors: Bruce McKay Morton, Thomas James Rollins) and assigned in common with the present invention and entitled “Communication System” describes methods and apparatus for driving the transducer with complex vibration signals.

Furthermore the transducer 112 may be driven in response to a user's manual operation of the touch screen 104 in order to provide tactile feedback to the user. U.S. patent application Ser. No. 10/160,589 filed Jun. 3, 2002 (attorney docket no. PT1291V, Inventors Thomas James Rollins, Bruce McKay Morton) and assigned in common with the present invention and entitled “Manually Operable Electronic Apparatus” describes methods and apparatus for driving the transducer in order to provide tactile feedback to the user.

The voltage used to drive the electroluminescent lamp 130 is typically several tens to a few hundred volts depending on the details of the lamp 130 construction. Similarly, the voltage used to drive the piezoelectric transducer 112 is typically in the range from a few tens to a hundred volts. On the other hand batteries used in portable electronic devices typically output power at voltage in the range of 1.5 to 9 volts.

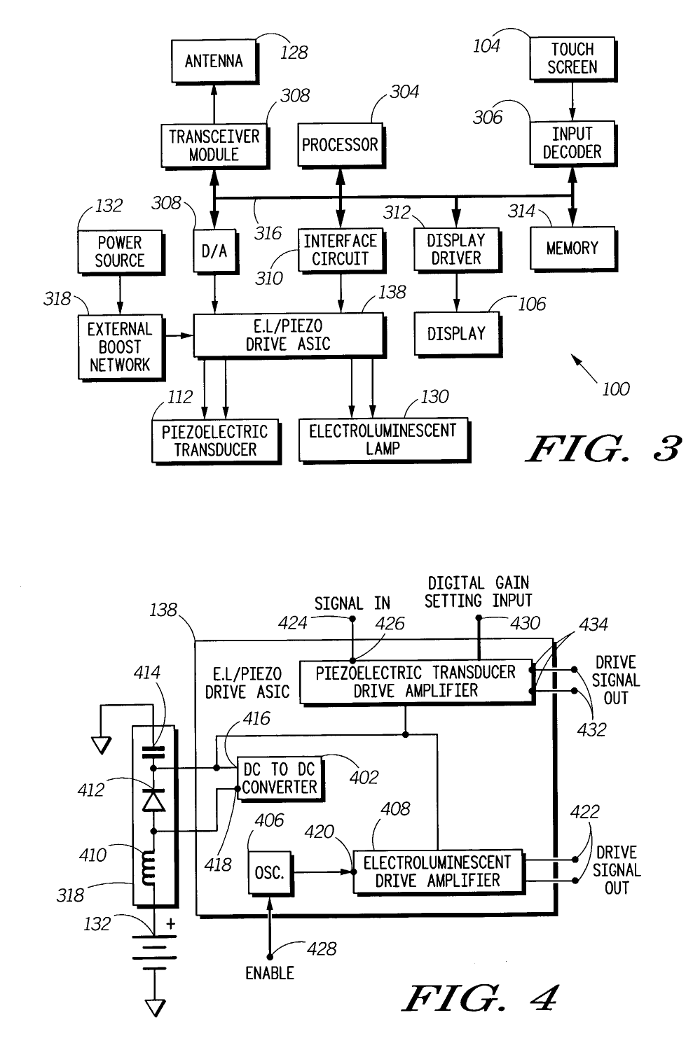

FIG. 3 is a block diagram of the portable electronic apparatus 100 shown in FIG. 1. As shown in FIG. 3, the portable electronic apparatus 100 comprises a transceiver module 302, a processor 304 (e.g., a digital signal processor), an input decoder 306, a digital to analog converter 308, an interface circuit 310, a display driver 312, and a memory 314 coupled together through a digital signal bus 316. The processor 304 serves to execute programs for controlling the operation of the portable electronic apparatus 100 that are stored in the memory 314.

The antenna 128 is coupled to the transceiver module 302. The touch screen 104 is coupled to the input decoder 306. In response to a user pressing the touch screen 104, the input decoder 306 outputs data that identifies a position on the touch screen 104 that was pressed. The position identifying data is read by processor 304. Thus, the apparatus 100 can be controlled by user input through the touch screen 104. The display driver 312 is coupled to the display 106.

The interface circuit 310 is coupled to the ASIC 138. The interface circuit 310 serves a peripheral interface function allowing the processor 304 to set values of digital inputs of the ASIC 138. The interface circuit 310 can for example comprise one or more address decoders and buffers. Using address decoders allow the processor 304 to access the ASIC by selecting a predetermined location in its address space. Buffers allow values written by the processor 304 to remain active after the processor 304 clock cycle in which they are written.

The piezoelectric transducer 112 and the electroluminescent lamp 130 are coupled to the ASIC 138, and driven by the ASIC 138. The power source 132 is coupled through an external boost network 318 to the ASIC 138. As will be described below in more detail the ASIC 138 works with the external boost network 318 to boost a voltage that characterizes power supplied by the power source 132.

FIG. 4 shows a block diagram of the ASIC 138 that is used in the portable electronic apparatus shown in FIG. 1 according to the preferred embodiment of the invention, along with the external boost circuit 318 and power source 132.

The ASIC 138 comprises a DC to DC converter 402, a piezoelectric transducer drive amplifier 404, an oscillator 406, and an electroluminescent drive amplifier 408.

As shown in FIG. 4, the external boost circuit 318 comprises an inductor 410, a diode 412, and a capacitor 414 in series. The inductor 410 is coupled to the anode of the diode 412, and to the power source 132. The cathode of the diode 412 is coupled to a first terminal of the capacitor 414. A second terminal of the capacitor 414 is coupled to ground.

The DC to DC converter 402 includes a first terminal 416 that is coupled to the junction of the diode 412 and the capacitor 414. The voltage at the junction of the diode 412 and the capacitor 414 is the nominal output voltage of the DC to DC converter 402. The DC to DC converter 402 includes a second terminal 418 that is coupled to the junction of the inductor 410 and the diode 412. In operation, the DC to DC converter 402 periodically couples the junction of the inductor 410 and the diode 412 to ground for a certain time interval, and subsequently opens the connection to ground. During the period that the junction of the inductor 410 and the diode 412 is connected to ground, current flowing through the inductor 410 builds. When the connection is opened, current flows through the diode 412 and charges the capacitor 414, thereby maintaining a relatively high voltage on the capacitor 414. In other words, energy stored in the inductor 410 is transferred to the capacitor 414. By controlling the duration of the periods during which the junction of the inductor 410 and the diode 412 are coupled to ground the magnitude of the current developed in the inductor 410 and the voltage developed across the capacitor 414 is controlled. The output voltage of the DC to DC converter 402 (the voltage across capacitor 414) can be controlled by using variously modulated signals to control the coupling of the junction of the inductor 410 and the diode 412 to ground. Such variously modulated signals are preferably controlled on the basis of feedback of the voltage developed across the capacitor 414. The workings of DC to DC converters are known to persons of ordinary skill in the art.

The first terminal 416 of the DC to DC converter 402 is also coupled to the piezoelectric transducer drive amplifier 404, and the electroluminescent drive amplifier 408. The DC to DC converter 402 supplies power (via the first terminal 416) that is characterized by a voltage that exceeds a voltage that characterizes the power source 132, to the piezoelectric transducer drive amplifier 404 and the electroluminescent drive amplifier 408.

The oscillator 406 is coupled to an electroluminescent drive amplifier input 420. The electroluminescent drive amplifier 408 amplifies an oscillating signal received from the oscillator 406 and outputs a high voltage electroluminescent lamp drive signal at a pair of electroluminescent drive amplifier outputs 422. The oscillator 406 comprises an enable input 428 that is coupled to the processor 304 through the interface circuit 310 and the digital signal bus 316.

The ASIC 138 comprises a piezoelectric drive signal input 424 that is coupled to a piezoelectric transducer drive amplifier input 426. The piezoelectric drive signal input 424 is coupled to the digital to analog converter 308 in the portable electronic apparatus 100. The piezoelectric transducer drive amplifier 404 amplifies signals output by the digital to analog converter 308. Alternatively, other signal sources are coupled to the piezoelectric drive signal input 424. Amplified versions of the signals received through the piezoelectric drive signal input 424 are output on a differential pair of piezoelectric transducer drive amplifier outputs 434. The piezoelectric transducer drive amplifier outputs 434 are coupled to a pair of differential piezoelectric drive signal outputs 432 of the ASIC 138. Signals that can be input at the piezoelectric drive signal input 424, include vibration signals, audio signals (e.g., music or voice signals), and signals that include one or more step function approximations. The latter signals are useful in driving the piezoelectric transducer 112 in order to provide tactile feedback. The signals used to drive the piezoelectric transducer can be received through the transceiver module 302.

The piezoelectric transducer drive amplifier 404 comprises a digital gain setting input 430 that is one or more bits wide. The digital gain setting input 430 is coupled to the processor 304 through the interface circuit 310, and the digital signal bus 316.

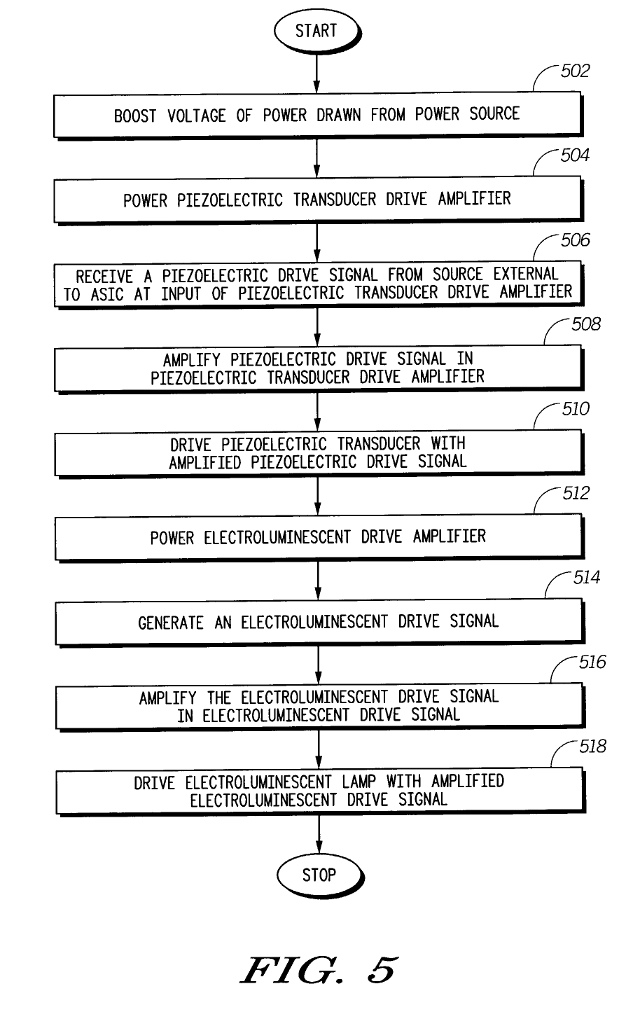

FIG. 5 is a flow chart of a method of operating the ASIC 138 shown in FIG. 4 according to the preferred embodiment of the invention. In step 505 the voltage of power drawn from the power source 132 is boosted. In step 504 the piezoelectric transducer drive amplifier 404 is powered at an increased voltage (relative to the power source 132). In step 506 a piezoelectric drive signal is received from a source external to the ASIC 138 (e.g. digital to analog converter 308) at the piezoelectric transducer drive amplifier input 426. In step 508 the piezoelectric drive signal is amplified within the piezoelectric transducer drive amplifier 404. In step 510 the piezoelectric transducer 112 is driven with an amplified piezoelectric drive signal produced in step 508. In step 512 the electroluminescent drive amplifier 408 is powered at an increase voltage (relative to the power source 132). In step 514 an electroluminescent drive signal is generated (e.g., by operating oscillator 406). In step 516 the electroluminescent drive signal is amplified in the electroluminescent drive amplifier 408, and in step 518 the electroluminescent lamp 130 is driven with an amplified electroluminescent drive signal produced in step 516.

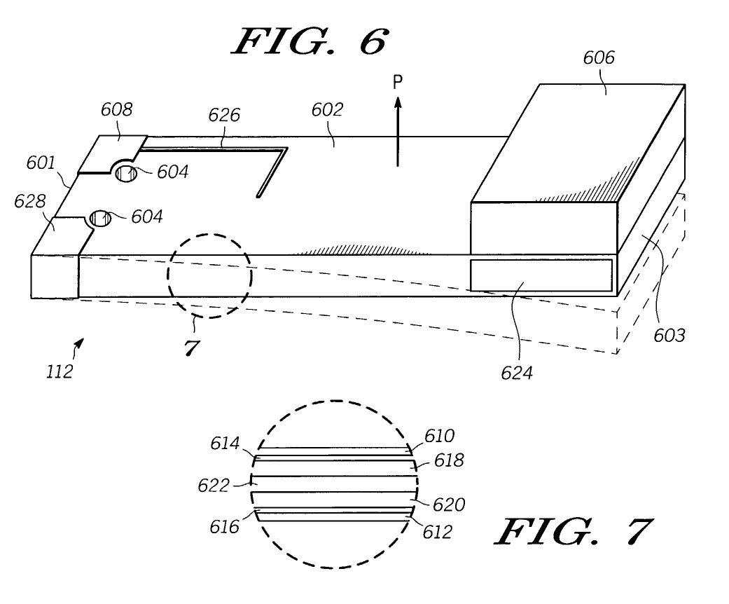

FIG. 6 is a perspective view of a piezoelectric transducer 112 that is used in the portable electronic apparatus shown in FIGS. 1-3 and FIG. 7 is a magnified view of a portion of the piezoelectric transducer shown in FIG. 6. The transducer 112 includes a flat beam piezoelectric motor 602. A first end 601 of the flat beam 602 is provided with two through holes 604 that are used to mount the transducer 112 on the mounting boss 116. A mass 606 is supported at a second end 603 of the beam 602. The second end 603 of the beam 602 is free to move. A first electrical contact 608, and a second electrical contact 628 are located proximate the first end 601 of the beam 602. The transducer 112 is driven by signals applied (e.g., through the fourth electrical coupling 118) to the first and second contacts 608, 628.

The beam 602 includes a plurality of layers as will be described presently. A first outer mylar layer 610 forms one side of the beam 602, and a second outer mylar layer 612 forms an opposite side of the beam 602. A first silver film layer 614, and a second silver film layer 616 are located between the first and second mylar layers 610, 612. A first piezoelectric layer 618 and a second piezoelectric layer 620 are located between the first and second silver film layers 614, 616. A brass shim 622 is located between the first and second piezoelectric layers 618, 620. The recited layers are bonded together using heat cured epoxy. The recited layered structure preferable extends over a middle portion of the beam 602. The layered structure need not extend under the mass 606 or to the first end 603. A brass plate 624 is preferably located between the first and second outer mylar layers 610, 612 underneath the mass 606. The first and second piezoelectric layers 616, 618 are preferably polarized parallel to each other and perpendicular to the top and bottom major surfaces of the beam 602. An exemplary polarization direction is indicated by vector P. The first and second silver film layers 614, 616 are preferably electrically connected to the first electrical contact 608 by a first metallization trace 626, and a second metallization trace (not shown) that run between the outer mylar layers 610, 612 and the silver film layers 614, 616. The brass shim 622 is preferably electrically connected to the second electrical contact 628. The brass shim 622 along with the first and second silver film layers 610, 612 serve as planar electrodes for applying electric fields to the piezoelectric layers 618, 620.

If the first electrical contact 608 is coupled to a first pole of a signal source, and the second electrical contact 628 is connected to a second pole of the signal source, oppositely directed electric fields will be established in the first and second piezoelectric layers 618, 620. Such oppositely directed fields will induce one of the piezoelectric layers 618, 620 to expand, and the other of the piezoelectric layers 618, 620 to contract. The simultaneous expansion of one of the piezoelectric layers 618, 620 and contraction of the other of the piezoelectric layers 618, 620, will cause the beam 602 to bow, and the mass 606 to be displaced perpendicularly with respect to the length of the beam 602. A somewhat exaggerated depiction of the deflected beam 602, without the mass 602, is shown by shadow lines. If the polarity of the signal source coupled to the first and second electrical contacts 608, 628 is reversed, the beam 602 will deflect in an opposite sense. Applying an oscillating signal to the transducer 112 will cause it to vibrate. If the oscillating signal includes a frequency component that corresponds to a resonant frequency of the transducer 112, the vibration amplitude of the transducer 112 will be high. The weight of the mass 606 is preferably selected in view of the stiffness of the transducer 112 to obtain a resonant frequency in the range of several tens to a couple hundred Hertz. Such a frequency is especially suited to generating perceptible vibratory alerts. Applying an audio signal to the transducer 112 will cause the transducer to emit sound according to the audio signal. Applying a drive signal that includes a pulse that includes an approximation of a step function will cause the transducer 112 to abruptly displace in such a manner as to produce an impulse of mechanical energy that may be felt by a user operating the portable electronic apparatus 100. Although the voltage amplitude necessary to drive the transducer 112 is dependent on the specific design details such as thickness of the piezoelectric layers 618, 620, generally speaking for piezoelectric transducer of the type illustrated in FIG. 6, driving voltages are generally in the range of a few tens to one-hundred volts. As described above the piezoelectric transducer 112 has a number of possible uses within the portable electronic apparatus 100.

Electroluminescent lamps such as may be used as the electroluminescent lamp 130 of the portable electronic apparatus 100 generally also require drive signal levels in the range of several tens to hundreds of volts depending on the specifics of their design (e.g., phosphor layer thickness).

Thus, both the piezoelectric transducer 112, and the electroluminescent lamp 130 ordinarily require relatively high voltages compared to the voltage that characterizes power sources (e.g., batteries) that are typically used to power portable electronic devices. By providing the ASIC 138 that includes the DC to DC converter 402 for boosting the voltage of the power source 132, and includes the piezoelectric transducer drive amplifier 404 for driving the piezoelectric transducer 112 based on signals input at the piezoelectric drive signal input 424, and the electroluminescent drive amplifier for driving the electroluminescent lamp 130 efficiency and economy in the construction of the portable electronic apparatus 100 is realized.

Although the use of the ASIC 138 in a portable electronic apparatus of a particular form factor has been described above, the ASIC 138 can be used other types of electronic apparatus including, but not limited wireless telephones, portable electronic games, portable talking electronic dictionaries, pagers, two-way pagers,

While the preferred and other embodiments of the invention have been illustrated and described, it will be clear that the invention is not so limited. Numerous modifications, changes, variations, substitutions, and equivalents will occur to those of ordinary skill in the art without departing from the spirit and scope of the present invention as defined by the following claims.

What is claimed is:

1. An application specific integrated circuit comprising:
a DC-to-DC converter adapted to increase a voltage that characterizes power supplied by an external power source;
a piezoelectric drive signal input;
a piezoelectric drive signal output;
a piezoelectric transducer drive amplifier comprising:
a piezoelectric transducer drive amplifier input coupled to the piezoelectric drive signal input
a piezoelectric transducer drive amplifier output coupled to the piezoelectric drive signal output;
wherein the piezoelectric transducer drive amplifier is adapted to receive power from the DC-to-DC converter, receive a piezoelectric drive signal through the piezoelectric drive signal input; and
output an amplified piezoelectric drive signal through the piezoelectric drive signal output.

2. The application specific integrated circuit according to claim 1 further comprising:
an electroluminescent drive amplifier adapted to receive power from the DC-to-DC converter, and output an electroluminescent drive signal.

3. The application specific integrated circuit according to claim 2 further comprising:
an oscillator, and
wherein the electroluminescent drive amplifier comprises an input coupled to the oscillator.

4. An electronic apparatus comprising:
a piezoelectric transducer;
an application specific integrated circuit comprising:
a DC-to-DC converter adapted to increase a voltage that characterizes power supplied by an external power source;
a piezoelectric drive signal input;
a piezoelectric drive signal output;
a piezoelectric transducer drive amplifier comprising:
a piezoelectric transducer drive amplifier input coupled to the piezoelectric drive signal input
a piezoelectric transducer drive amplifier output coupled to the piezoelectric drive signal output;
wherein the piezoelectric transducer drive amplifier is adapted to receive power from the DC-to-DC converter, receive a piezoelectric drive signal through the piezoelectric drive signal input; and
output an amplified piezoelectric drive signal through the piezoelectric drive signal output.

5. An integrated circuit comprising:
a first means for boosting a voltage that characterizes power supplied by an external power source;
a second means that is powered by the first means for receiving an externally produced piezoelectric drive signal amplifying the piezoelectric drive signal, and outputting an amplified piezoelectric drive signal.

6. The integrated circuit according to claim 1 further comprising:
a third means that is powered by the first means for outputting an electroluminescent lamp drive signal.

7. A method for operating an application specific integrated circuit comprising the steps of:
boosting a voltage that characterizes power drawn from a power source;
powering a first amplifier;
receiving a piezoelectric drive signal from at an input of the application specific integrated circuit at an input of the first amplifier;
amplifying the piezoelectric drive signal in the first amplifier to produce an amplified piezoelectric drive signal; and
driving a piezoelectric transducer with the amplified piezoelectric drive signal.

8. The method according to claim 7 further comprising the steps of:
powering an electroluminescent drive amplifier;
generating an electroluminescent drive signal;
amplifying the electroluminescent drive signal with the electroluminescent drive amplifier to produce an amplified electroluminescent drive signal; and
driving an electroluminescent lamp with the amplified electroluminescent drive signal.
